(19) United States
(12) Patent Application Publication
(10) Pub. No.: US 2007/0249191 A1
(43) Pub. Date: Oct. 25, 2007

(54) Printed circuit board

(75) Inventor: Zheng Yan, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/789,094

(22) Filed: Apr. 23, 2007

(30) Foreign Application Priority Data
Apr. 21, 2006 (TW) 95114355

(51) Int. Cl. H05K 1/00

(52) U.S. Cl. 439/83

(57) ABSTRACT

An exemplary printed circuit board (200) has a substrate (210); a circuit (230) on the substrate; and a plurality of pins (220) peripherally located on the substrate, electrically connected to the circuit. The printed circuit board further has a plurality of accommodating spaces (223) formed at the plurality of pins.

### BACKGROUND OF THE INVENTION

1. Field of the Invention

The present invention relates to liquid crystal displays (LCDs), and particularly to an LCD with in-plane switching (IPS) mode and providing a highly precise alignment of liquid crystal molecules therein.

2. General Background

Conventional chip packages such as leadframe-based Chip Scale Packages (CSPs) are soldered onto PCBs using solder paste. Leadframe-based CSPs are CSPs having no peripheral leads that typically extend out from chip packages. A conventional leadframe-based CSP includes a leadframe divided into a die attach. pad centrally located therein and a plurality of wire bonding pads peripherally located therein. The conventional leadframe-based CSP further includes one or more dies or chips mounted on the die attach pad, bonding wires for electrically connecting the dies to the wire bonding pads, and a mold compound for encapsulating all these components in a package structure. A variety of different types of leadframe-based CSPs are available in the market, such as Micro-Lead Packages (MLPs), Micro-Lead-Frames (MLFs), Leadless Package Chip Carriers (LPCC), etc. Joint Electron Device Engineering Counsel (JEDEC), which is a committee for establishing industry standards and packaging outlines, has defined a package outline named “MO-220” for leadframe-based CSPS.

A typical PCB is made of conductive layers and dielectric layers stacked up in an alternating manner. The top conductive layer on the PCB is divided into a center pad centrally located therein and a plurality of I/O (input/output) pins peripherally located therein. Typically, solder paste is deposited on certain portions of the center pad and the I/O pins. An electronic package such as a leadframe-based CSP is then placed onto the PCB and fixedly mounted thereon by solder paste. During the mounting of the leadframe-based CSP, the die attach pad of the leadframe-based CSP is aligned with the center pad of the PCB and the wire bonding pads of the leadframe-based CSP are aligned with the I/O pins of the PCB.

As shown in FIG. 5 and FIG. 6, a typical PCB is disclosed. The PCB 100 includes a substrate 110, a circuit 130 centrally located thereon and a plurality of I/O pins 120 peripherally located thereon. The plurality I/O pins 120 are rectangular copper foil, which are parallel to each other, extending along a first extending direction. The plurality I/O pins 120 is connected to the circuit 130 for electrically connecting the circuit 130 with an outer PCB or other outer elements.

FIG. 6 is a partially enlarged, cross-sectional view of the PCB of FIG. 1, taken along a line VI-VI. The plurality of pins 120 formed on the substrate 110 has a plurality of guiding textures 121, and a soldering flux 122 covering an external surface of the pins 120. The soldering flux 122 is generally made from tin or anisotropic conductive film. The guiding texture 121 extends along the first extending direction of the pins 120, which is used to guide the flowing direction of the melting soldering flux 122 when an outer element is soldered on the pins 120. The guiding texture 121 can prevent short circuit between two adjacent pins 120, which is influenced by overflow of the melting soldering flux 122 from two sides of the pins 120.

However, some superfluous melting soldering flux 122 flows to tail ends of the pins 120 or concentrates at the tail end to form a solder ball, under a pressure thereon produced in the process of bonding the outer elements on the PCB 100. Thus, a short circuit is easy to produce when the soldering flux 122 is thicker or a pitch between two adjacent pins 120 is small (as shown in FIG. 7).

Thus, what is needed is an improved PCB which can overcome the above-mentioned disadvantages.

### SUMMARY OF THE INVENTION

An exemplary printed circuit board has a substrate; a circuit on the substrate; and a plurality of pins peripherally located on the substrate, electrically connected to the circuit. The printed circuit board further has a plurality of accommodating spaces formed at the plurality of pins.

Another exemplary printed circuit board has a substrate; a circuit on the substrate; and a plurality of pins peripherally located on the substrate, electrically connected to the circuit. The printed circuit board further has at least one opening are formed at the plurality of pins.

Other objects, advantages and novel features of the invention will become more apparent from the following detailed description when taken in conjunction with the accompanying drawings.

### BRIEF DESCRIPTION OF THE DRAWINGS

FIG. 1 is a plane view of a PCB in accordance with a first preferred embodiment of the present invention;

FIG. 2 is a partially enlarged cross-sectional view of the PCB of FIG. 1 taken along a line II-II;

FIG. 3 is a plane view of a PCB in accordance with a second preferred embodiment of the present invention;

FIG. 4 is a plane view of a PCB in accordance with a third preferred embodiment of the present invention;

FIG. 5 is a plane view of a conventional PCB;

FIG. 6 is a partially enlarged cross-sectional view of the PCB of FIG. 5. taken along a line VI-VI; and

FIG. 7 is plane view of the PCB of FIG. 5, showing a short circuit phenomenon.

### DETAILED DESCRIPTION OF THE PREFERRED EMBODIMENT

Hereinafter, a preferred embodiment of the present invention will be explained in more detail with reference to the accompanying drawings.

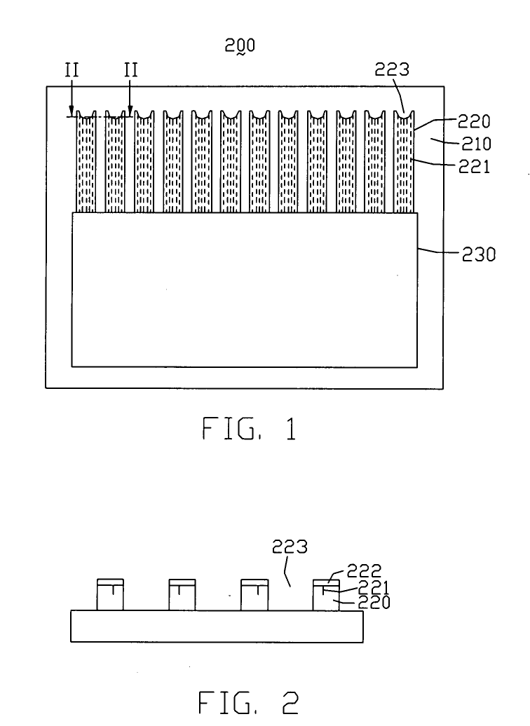

Referring to FIG. 1, a plane view of a PCB according to a preferred first embodiment of the present invention is shown. FIG. 2 is a partially enlarged, cross-sectional view of the PCB of FIG. 1, taken along a line of II-II. The PCB 200 has a substrate 210, a circuit 230 centrally located thereon and a plurality of I/O pins 220 peripherally located thereon. The plurality I/O pins 220 are rectangular copper foil, which are parallel to each other, extending along a first extending direction. Two adjacent pins 220 are insulated. The plurality I/O pins 220 are connected to the circuit 130 for electrically connecting the circuit 230 with an outer element.

The plurality of pins 220 formed on the substrate 210 has a plurality of guiding textures 221 formed at an external surface of the pins 220, a soldering flux 222 covering the external surface, and an accommodating space 223 at a tail end of each pin 220. The soldering flux 222 is generally made from tin or anisotropic conductive film. The guiding texture 221 extends along the first extending direction of the pins 220, which is used to guide the flowing direction of the melting soldering flux 222 when an outer element is soldered on the pins 220. The accommodating space 223 is a depressed portion at the tail end of the pins 220, which has a deepness same to a thickness of the pins 220.

In use, when an outer element is bonded on the pins 220 of the PCB 200, the guiding textures 221 guide the melting soldering flux 222 flowing along the first extending direction of the guiding textures 221. The guiding texture 221 can prevent overflow of the melting soldering flux 222 from two sides of the pins 220, and avoid short circuit between two adjacent pins 220 or forming soldering ball or forming soldering joints. And, superfluous melting soldering flux 222 can flow in the accommodating space 223. Thus, amount of the superfluous melting soldering flux 222 can be lessened, and the probability of producing the short circuit can be lowered.

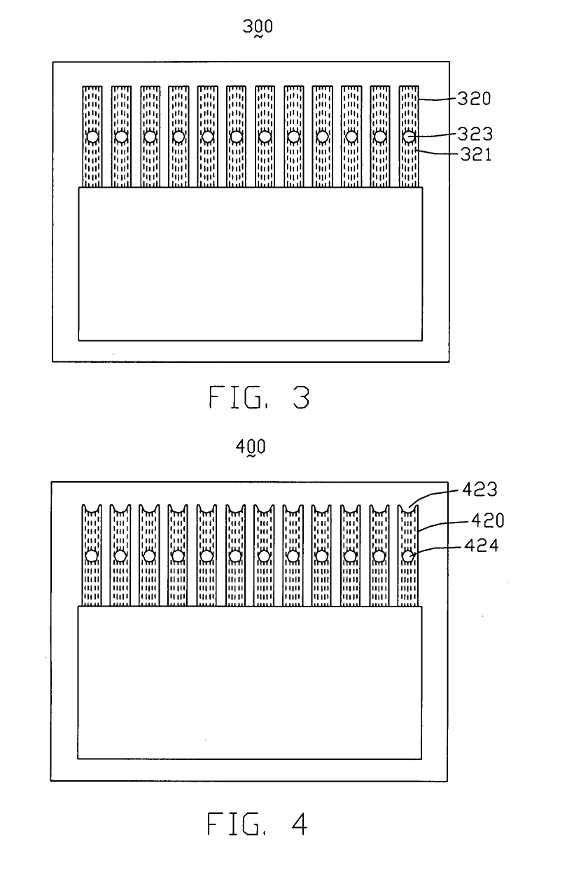

FIG. 3 shows a PCB according to a second preferred embodiment of the present invention. The PCB 300 has a similar structure to that of the PCB 200 except that an accommodating space 323 is formed at a center region of pins 320, which is a concave hole or a through hole. In use, when an outer element is bonded on the pins 320 of the PCB 300, a plurality of guiding textures 321 of the pins 320 guide the melting soldering flux (not shown) flowing along the first extending direction of the guiding textures 321. The guiding texture 321 can prevent overflow of the melting soldering flux from two sides of the pins 320, and avoid short circuit between two adjacent pins 320 or forming solder ball. And, superfluous melting soldering flux can flow in the accommodating space 323. Thus, amount of the superfluous melting soldering flux can be lessened, and the probability of producing the short circuit can be lowered.

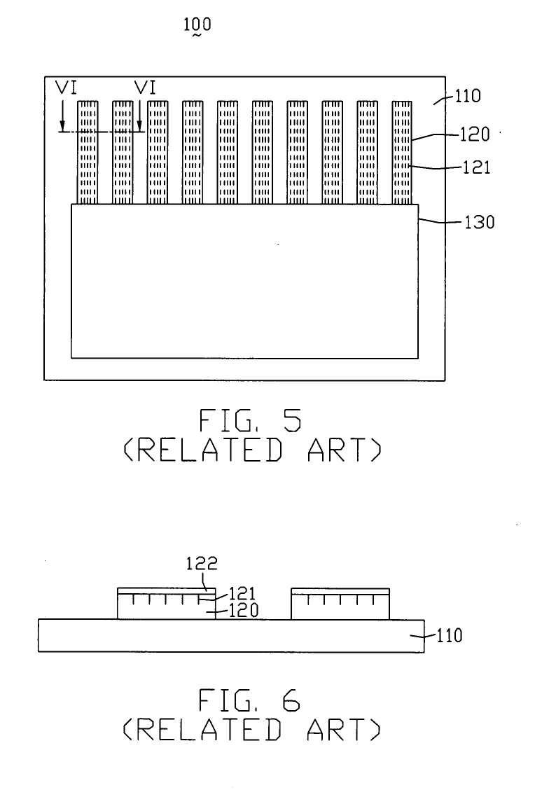

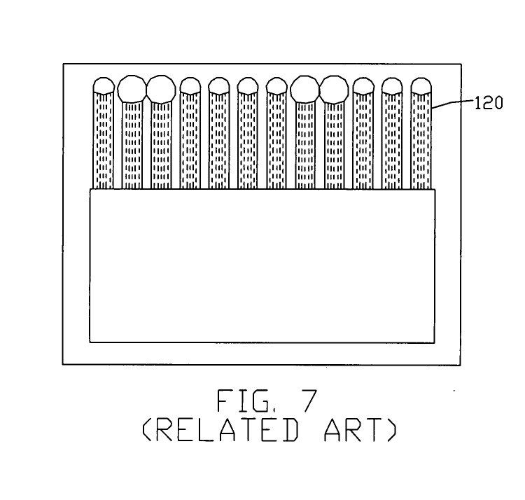

FIG. 4 shows a PCB according to a third preferred embodiment of the present invention. The PCB 400 has a similar structure to that of the PCB 200 except that a first accommodating space 423 and a second accommodating space 424 are formed. The first accommodating space 423 is formed at a tail end of each pin 420, which is a depressed portion, and the second accommodating space 424 is formed at a center region of each pin 420, which is a concave hole. In use, when an outer element is bonded on the pins 420 of the PCB 400, a plurality of guiding textures (not labeled) of the pins 420 guide the melting soldering flux (not shown) flowing along the extending direction of the guiding textures. The guiding texture can prevent overflow of the melting soldering flux from two sides of the pins 420, and avoid short circuit between two adjacent pins 420 or forming solder ball. And, superfluous melting soldering flux can flow in the accommodating spaces 423, 424. Thus, amount of the superfluous melting soldering flux can be lessened, and the probability of producing the short circuit can be lowered.

In various alternate modifications, the accommodating space can be formed at other positions of the pins. Each pin can have one or two or more than three accommodating space. The deepness of each pin can be equal to or higher than or lower than the thickness of corresponding pin.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

We claim:

1. A printed circuit board (PCB), comprising:
a substrate;
a circuit on the substrate; and
a plurality of pins peripherally located on the substrate, electrically connected to the circuit;
wherein a plurality of accommodating spaces are formed at the plurality of pins.

2. The PCB as claimed in claim 1, wherein the accommodating space is formed at a tail end of the pin.

3. The PCB as claimed in claim 1, wherein the accommodating space is formed at a center region of the pin.

4. The PCB as claimed in claim 1, wherein each pin comprises at least one accommodating space.

5. The PCB as claimed in claim 1, wherein each pin comprises two accommodating spaces, one being formed at a tail end of the pin and the other being formed at a center region of the pin.

6. The PCB as claimed in claim 1, wherein the accommodating space is a depressed portion.

7. The PCB as claimed in claim 1, wherein the accommodating space is a concave hole or a through hole.

8. The PCB as claimed in claim 1, wherein two adjacent pins are insulated.

9. The PCB as claimed in claim 1, wherein each pin comprises a plurality of guiding texture, having an extending direction same to that of the pin.

10. The PCB as claimed in claim 1, further comprising a soldering flux covering each pin.

11. The PCB as claimed in claim 1, wherein the soldering flux can be tin or anisotropic conductive film.

12. The PCB as claimed in claim 1, wherein a deepness of the accommodating space is equal to a thickness of the pin.

13. The PCB as claimed in claim 1, wherein a deepness of the accommodating space is larger than a thickness of the pin.

14. The PCB as claimed in claim 1, wherein a deepness of the accommodating space is smaller than a thickness of the pin.

15. A printed circuit board, comprising:
a substrate;
a circuit on the substrate; and
a plurality of pins peripherally located on the substrate, electrically connected to the circuit;
wherein at least one opening are formed at the plurality of pins.
